(19) United States
(12) Patent Application Publication
(10) Pub. No.: US 2014/0151105 A1
(43) Pub. Date: Jun. 5, 2014

(54) BASE SUBSTRATE, RESONATOR, OSCILLATOR, SENSOR, ELECTRONIC DEVICE, ELECTRONIC APPARATUS, AND MOVING OBJECT

(71) Applicant: SEIKO EPSON CORPORATION, Tokyo (JP)

(72) Inventor: Takuo KUWAHARA, Tatsuno-machi (JP)

(73) Assignee: SEIKO EPSON CORPORATION, Tokyo (JP)

(21) Appl. No.: 14/093,212

(22) Filed: Nov. 29, 2013

(30) Foreign Application Priority Data
Dec. 4, 2012 (JP) 2012-265017

(51) Int. Cl. H05K 1/18; H03B 5/32

(52) U.S. Cl. CPC H05K 1/181; H03B 5/32
USPC 174/260; 331/158; 174/250

(57) ABSTRACT

An insulating container as a base substrate includes a loading portion which is disposed on the other surface side, mounting electrodes as first terminals which are provided on a bottom surface as the other surface having a front and rear relationship with the other surface, a first cut-out portion which is provided on a side surface from a corner portion of the bottom surface towards a corner portion on the other surface side, a second cut-out portion which is provided to extend from the first cut-out portion at least on one of the side surfaces on both sides of the first cut-out portion, and second terminals which are provided on the surface of the first cut-out portion and the surface of the second cut-out portion.

### BACKGROUND

1. Technical Field

The present invention relates to a base substrate, a resonator using the base substrate, an oscillator, a sensor, an electronic device, an electronic apparatus, and a moving object.

2. Related Art

There is known, for example, a surface-mounted electronic device having a configuration of loading various circuit components or the like on a wiring pattern which is formed on a surface of an insulating substrate including a mounting electrode on a bottom portion (rear surface). As such a surface-mounted electronic device, for example, a quartz crystal resonator or a quartz crystal oscillator can be used, and the surface-mounted electronic device has a configuration of loading a piezoelectric vibrating element on the inside of a recess of the surface of an insulating container (insulating substrate) such as ceramics including a mounting electrode on a bottom portion and hermetically sealing the recess with a cover.

In the insulating container of the electronic device which is formed of ceramics or the like, in order to secure conductivity between the mounting electrode which is provided on a container bottom surface, and the inside of the container, a castellation having an arc-like shape of a side wall in a plan view is formed on a corner portion of the container bottom surface, and a conductive film which is electrically connected with the mounting electrode is formed on the side wall. The arc-like castellation is effective for preventing solder cracks which occur due to a difference in a coefficient of thermal expansion between a configuration material of the container and a motherboard circuit board (glass epoxy or the like) including a land for solder connection of the mounting electrode on the container bottom surface. That is, since the container formed of a low thermal expansion material such as ceramics is, in general, solder-connected on the land of the motherboard circuit board formed of glass epoxy or the like, if a thermal load is applied thereto after a certain period, maximum strain occurs on a corner portion of the solder joint portion which is in a position separated farthest from a center portion of the rectangular container bottom surface, and accordingly cracks easily occur on the solder.

In order to prevent occurrence of cracks on the solder-joint portion on the corner portion, as shown in FIG. 14, there has been proposed a configuration of providing castellations 121 and 122 which have a predetermined length from the corner portion of the base substrate (container) 120 towards both sides, and on a surface of which electrodes 124 and 125 are formed, shortening a distance between the corner portion (corner portion 127) and the center portion of the container bottom surface, and increasing solder fillet amounts 130 and 131 to increase joining strength with a connection electrode 135 of the motherboard circuit board (printed circuit board) (for example, see JP-A-2006-196703).

As shown in FIG. 14, in the configuration of the related art, the castellations 121 and 122 which are the cut-out portions having a predetermined length from the corner portion 127 of the insulating container (base substrate 120) formed of ceramics or the like including the mounting electrode (not shown) on the bottom surface of the container towards both sides are provided, and an intersection of the castellations 121 and 122 on both sides is the corner portion 127.

However, if such a corner portion 127 is provided, at the time of solder connecting with the connection electrode 135 of the motherboard circuit board (printed circuit board), a region 140 in which the solder fillet for the corner portion 127 is not easily formed, is generated due to repulsion of surface tension between solder fillets (skirt shapes of solder) 130 and 131 formed on the castellations 121 and 122 on both sides. That is, since a region having insufficient connection strength exists due to decrease of solder amounts (solder fillets) on the corner portion 127 on which the maximum strain occurs when thermal load is applied, there is a concern that cracks on the solder easily occur when thermal load is applied thereto.

### SUMMARY

An advantage of some aspects of the invention is to solve at least a part of the problems described above, and the invention can be implemented as the following forms or application examples.

### Application Example 1

This application example is directed to a base substrate including a substrate which has corner portions and cut-out portions obtained by connecting side surfaces on both sides of the corner portions, in a plan view, and in which an outer periphery of the corner portion is a curved line, in a plan view, in which a metallic film is provided on a surface of each of the cut-out portions.

According to this application example, the base substrate includes first terminal portions (mounting terminals) on one surface, first cut-out portions on the side surfaces of the corner portions, and second cut-out portions on the side surfaces of both sides, which extend from the first cut-out portions having a curved outer periphery, and second terminal portions (metallic films) are provided on the surfaces thereof. When soldering the base substrate of such a configuration on the motherboard circuit board (printed circuit board), in addition to the soldering of the first terminal portions, solder fillets having sufficient amounts are formed on the first cut-out portions provided on the corner portions of the base substrate and the second cut-out portions which extend from the first cut-out portions. As described above, when applying the thermal load to the soldered base substrate, the solder fillets having sufficient amounts are formed on the corner portions of the base substrate having maximum thermal stress, and accordingly it is possible to reduce malfunction such as occurrence of solder cracks due to the thermal load.

### Application Example 2

This application example is directed to the base substrate according to the application example described above, wherein the outer periphery of each of the corner portions is convexly recessed towards the center of the substrate, in a plan view.

According to this application example, since the first cut-out portion is a recess which is convexly recessed towards the center side of one surface, the solder at the time of soldering can be filled in the recess, and sufficient solder amounts can be secured. Accordingly, the solder fillets on the corner portions are stably formed with sufficient amounts, and reliability of soldering can be improved. That is, it is possible to suppress malfunction such as occurrence of solder cracks which occur due to the thermal load.

According to this application example, since the recess includes a curved line in a plan view, the area of the inner surface of the recess can be set larger, and accordingly the area of the soldering can be set larger. Therefore, strength of the soldering can be improved and the reliability of the soldering can be improved.

Accordingly, the solder fillets on the corner portions are stably formed with sufficient amounts, and reliability of soldering can be improved. That is, it is possible to suppress malfunction such as occurrence of solder cracks which occur due to the thermal load.

### Application Example 3

This application example is directed to the base substrate according to the application example described above, wherein the base substrate includes mounting terminals on one surface of the substrate, and concavity and convexity are provided on a surface of each of the mounting terminals.

According to this application example, it is possible to forma space for filling the solder on the periphery portion of the first terminal by the concavity and convexity. In addition, it is also possible to widen a space between the base substrate and the motherboard circuit board (printed circuit board) by the concavity and convexity. Accordingly, it is possible to increase the solder amounts at the time of soldering with the solder on the first cut-out portions and the second cut-out portions, and therefore strength of the soldering can be improved and the reliability of the soldering can be improved.

In the base substrate of this application example, the protrusion of the concavity and convexity may be disposed on the outer periphery side with respect to the center of the one surface.

According to this, it is possible to increase the solder amount on the center side of the one surface. Accordingly, when applying the thermal load, since it is possible to have a greater solder amount on the center portion side in which the deformation amount due to thermal expansion is relatively small, the reliability of the soldering can further be improved.

In addition, in the base substrate of this application example, a plurality of protrusions are provided on the surface of the first terminal.

According to this, since the solder can be filled in the spaces between the protrusions provided by the plurality of protrusions, it is possible to widen the surface area of the soldering. Therefore, strength of the soldering can be improved and the reliability of the soldering can be improved.

### Application Example 4

This application example is directed to a resonator including: the base substrate according to any one of the application examples; and a vibrating piece which is loaded on the base substrate.

According to this application example, since the resonator includes the base substrate described above, it is possible to sufficiently secure the solder amounts (solder fillets) at the time of soldering the base substrate on the motherboard circuit board (printed circuit board). Accordingly, it is possible to provide a resonator having high reliability which can reduce malfunction such as occurrence of solder cracks which occur due to the thermal load.

### Application Example 5

This application example is directed to an oscillator including: the base substrate according to any one of the application examples; a vibrating piece which is loaded on the base substrate; and a circuit which drives the vibrating piece.

According to this application example, since the oscillator includes the base substrate described above, it is possible to sufficiently secure the solder amounts (solder fillets) at the time of soldering the base substrate on the motherboard circuit board (printed circuit board). Accordingly, it is possible to provide an oscillator having high reliability which can reduce malfunction such as occurrence of solder cracks which occur due to the thermal load.

### Application Example 6

This application example is directed to a sensor including: the base substrate according to any one of the application examples; and a sensor element which is loaded on the base substrate.

According to this application example, since the sensor includes the base substrate described above, it is possible to sufficiently secure the solder amounts (solder fillets) at the time of soldering the base substrate on the motherboard circuit board (printed circuit board). Accordingly, it is possible to provide a sensor having high reliability which can reduce malfunction such as occurrence of solder cracks which occur due to the thermal load.

### Application Example 7

This application example is directed to an electronic device including: the base substrate according to any one of the application examples; and an electronic element which is loaded on the base substrate.

According to this application example, since the electronic device includes the base substrate described above, it is possible to sufficiently secure the solder amounts (solder fillets) at the time of soldering the base substrate on the motherboard circuit board (printed circuit board). Accordingly, it is possible to provide an electronic device having high reliability which can reduce malfunction such as occurrence of solder cracks which occur due to the thermal load.

### Application Example 8

This application example is directed to an electronic apparatus including the base substrate according to any one of the application examples.

According to this application example, since the electronic apparatus includes the base substrate described above, it is possible to sufficiently secure the solder amounts (solder fillets) at the time of soldering the base substrate on the motherboard circuit board (printed circuit board). Accordingly, it is possible to provide an electronic apparatus having high reliability which can reduce malfunction such as occurrence of solder cracks which occur due to the thermal load.

### Application Example 9

This application example is directed to a moving object including the base substrate according to any one of the application examples.

According to this application example, since the moving object includes the base substrate described above, it is possible to sufficiently secure the solder amounts (solder fillets) at the time of soldering the base substrate on the motherboard circuit board (printed circuit board). Accordingly, it is possible to provide a moving object having high reliability which can reduce malfunction such as occurrence of solder cracks which occur due to the thermal load.

### BRIEF DESCRIPTION OF THE DRAWINGS

The invention will be described with reference to the accompanying drawings, wherein like numbers reference like elements.

FIGS. 1A to 1C show a schematic configuration of a surface-mounted quartz crystal resonator according to one embodiment using a base substrate according to the invention, wherein FIG. 1A is a plan view, FIG. 1B is a front cross-sectional view, and FIG. 1C is a bottom view when FIG. 1A is seen from a rear surface side.

FIGS. 2A and 2B are views showing a state of solder fillets of a surface-mounted quartz crystal resonator according to one embodiment of the invention, wherein FIG. 2A is a perspective view and FIG. 2B is a cross-sectional view taken along line P-P of FIG. 2A.

FIGS. 3A and 3B show Modification Example 1 of mounting electrodes (first terminals), wherein FIG. 3A is a partial front view and FIG. 3B is a bottom view.

FIG. 4 is a bottom view showing Modification Example 2 of mounting electrodes (first terminals).

FIGS. 5A and 5B show Modification Example 3 of mounting electrodes (first terminals), wherein FIG. 5A is a partial front cross-sectional view and FIG. 5B is a bottom view.

FIGS. 6A and 6B show Modification Example 4 of mounting electrodes (first terminals), wherein FIG. 6A is a partial front view and FIG. 6B is a bottom view.

FIGS. 7A and 7B show Modification Example 5 of mounting electrodes (first terminals), wherein FIG. 7A is a partial front view and FIG. 7B is a bottom view.

FIGS. 8A and 8B are front cross-sectional views showing an oscillator using the base substrate according to the invention.

FIGS. 9A and 9B are front cross-sectional views showing an electronic device using the base substrate according to the invention.

FIG. 10 is a perspective view showing a configuration of a mobile personal computer as an example of an electronic apparatus.

FIG. 11 is a perspective view showing a configuration of a mobile phone as an example of an electronic apparatus.

FIG. 12 is a perspective view showing a configuration of a digital still camera as an example of an electronic apparatus.

FIG. 13 is a perspective view showing a configuration of an automobile as an example of a moving object.

FIG. 14 is a perspective view showing a state of solder fillets of an example of the related art.

### DESCRIPTION OF EXEMPLARY EMBODIMENTS

Hereinafter, the invention will be specifically described based on embodiments shown in the accompanied drawings. In the following embodiments, a surface-mounted quartz crystal resonator will be described as an example of a surface-mounted piezoelectric resonator using a base substrate according to the invention.

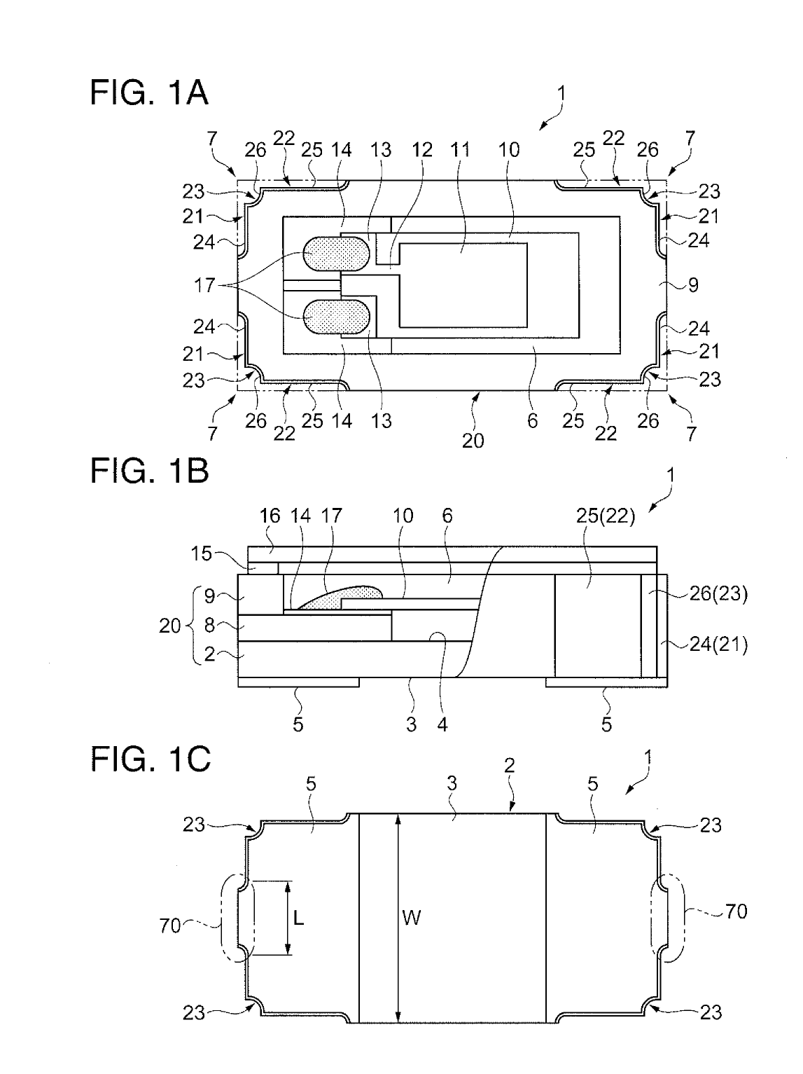

FIGS. 1A to 1C show a schematic configuration of the surface-mounted quartz crystal resonator according to one embodiment of the invention, wherein FIG. 1A is a plan view, FIG. 1B is a partial longitudinal front cross-sectional view, and FIG. 1C is a bottom view when FIG. 1A is seen from a rear surface side. In the plan view of FIG. 1A, a seal ring and a cover are omitted for convenience of description. The surface-mounted quartz crystal resonator is an example of a resonator.

A quartz crystal resonator 1 has a configuration of accommodating a quartz crystal vibrating element 10 in a loading portion 6 which is a recess of an insulating container (package) 20 as a base substrate obtained by laminating a first substrate 2, a second substrate 8, and a third substrate 9 which are formed of a sheet-like insulating material such as ceramic sheet, and sealing the loading portion 6 with a cover 16.

In the insulating container (package) 20 as the base substrate, the first substrate 2 as a bottom plate, the second substrate 8 as a loading plate of the quartz crystal vibrating element 10, and the third substrate 9 as an outer wall are laminated in this order. The insulating container 20 is a circuit wiring board having an approximately rectangular container shape in a plan view, and mounting electrodes (first terminals) 5 which are provided to contain two corners of a bottom surface (one surface) 3 of the approximately rectangular first substrate 2 are provided. The mounting electrodes (first terminals) 5 are, for example, conductive metallic layers having a configuration of performing gold (Au) plating on a burnt nickel (Ni) metallization layer as an underlaying metal. In the insulating container 20, the loading portion 6 which is a recess surrounded by an opening portion of the second substrate 8 and the third substrate 9 is provided on the other surface 4 side which has a front and rear relationship with the bottom surface 3 of the first substrate 2. The other surface 4 is a surface on a side of the insulating container 20 which is connected to the cover 16, and indicates one surface of the first substrate 2 in the drawing for the sake of convenience. Two inner pads 14 which are electrically connected to the quartz crystal vibrating element 10 are provided on an exposed surface of the second substrate 8 which is exposed in the loading portion 6. Each inner pad 14 is electrically connected to the corresponding mounting electrode 5, however the description thereof in the drawing is omitted.

In addition, in the approximately rectangular four corner portions 7 of the insulating container 20, first cut-out portions (castellation) 23 are provided on a side surface of the corner portions 7 of the insulating container 20, from the corner portion 7 of the first substrate 2 on the bottom surface 3 side towards the corner portions 7 on the other surface 4 side. That is, the first cut-out portions (castellation) 23 are provided on the side surfaces from the bottom surface 3 of the first substrate 2 to an upper surface of the third substrate 9 (surface on which the seal ring 15 for connecting the cover 16 is formed). The first cut-out portions 23 are formed to include curved lines and to be recessed towards the center side, when the insulating container 20 is seen in a plan view. In this example, the first cut-out portions are formed in a shape of a so-called arc-like recess.

In addition, a second cut-out portion 21 and a third cut-out portion 22 which are provided to extend from the first cut-out portion 23 are provided on both side surfaces of the insulating container 20 with the first cut-out portion 23 interposed therebetween. The second cut-out portion 21 and the third cut-out portion 22 are provided towards the other surface 4 side from the corner portion 7 of the first substrate 2 on the bottom surface 3 side, in the same manner as the first cut-out portion 23. That is, the second cut-out portion 21 and the third cut-out portion 22 are provided on the side surfaces from the bottom surface 3 of the first substrate 2 to the upper surface of the third substrate 9 (surface on which the seal ring 15 for connecting the cover 16 is formed), in the same manner as the first cut-out portion 23. When the insulating container 20 is seen in a plan view, the second cut-out portion 21 and the third cut-out portion 22 are recessed cut-out portions having a predetermined length from the outer periphery of the insulating container 20 towards the inside thereof, and each one end thereof is connected to the first cut-out portion 23. Each of the other ends which are extended from the one end connected to the first cut-out portion 23 with a predetermined length, is provided to have an arc shape.

Second terminals 26, 24, and 25 which are metallic layers are provided on the surfaces of the first cut-out portion 23, the second cut-out portion 21, and the third cut-out portion 22. That is, the second terminal 26 is formed on the surface of the first cut-out portion 23, the second terminal 24 is formed on the surface of the second cut-out portion 21, and the second terminal 25 is formed on the surface of the third cut-out portion 22. The second terminals 26, 24, and 25 are preferably formed with metal having excellent solder wettability for securing a soldering property of the quartz crystal resonator 1, which will be described later, and a configuration of performing gold (Au) plating on a burnt nickel (Ni) metallization layer as an underlaying metal is used, for example. The second terminals 26, 24, and 25 may have conductivity, and may also have a configuration to be used as electrode layers by being connected to the mounting electrode 5 as the first terminal. In addition, the configuration of the second terminals 26, 24, and 25 is one example, and the other metal may be used as long as it has a function as electrode layers or soldering layers.

A protrusion 70 is provided between the second cut-out portion 21 and the third cut-out portion 22. The mounting electrode (first terminal) 5 is also provided on the bottom surface 3 on which the protrusion 70 is formed. Accordingly, while an area of an adhesion region is decreased in a plan view, as the first cut-out portion 23 is provided on the corner portion 5, the area of the adhesion region can be increased (so-called earned) by an area of the mounting electrode 5 of a portion in which the protrusion 70 is provided, and strength of the solder joint is maintained not to be decreased, or is strengthened.

In addition, a width L of the protrusion 70 is preferably equal to or less than 50% (L/W≦50(%)) with respect to a width W of a package. Accordingly, in a manufacturing step of the base substrate, an amount of burr which occurs when breaking from the motherboard to individual pieces can be decreased.

In the description, the configuration of providing the second cut-out portion 21 and the third cut-out portion 22 which extend from the first cut-out portion 23 are provided on both side surfaces of the insulating container 20 with the first cut-out portion 23 interposed therebetween has been described, however the invention is not limited thereto. At least one cut-out portion of the second cut-out portion 21 and the third cut-out portion 22 which extend from the first cut-out portion 23 may be provided on the side surface of the insulating container 20.

In the quartz crystal vibrating element 10, an excitation electrode 11 is formed on front and rear main surfaces, and two connection electrodes 13 are provided through a wiring electrode 12 which is extended from the excitation electrode 11. The quartz crystal vibrating element 10 is electrically connected and fixed to the inner pad 14 which is provided in the loading portion 6 of the second substrate 8 configuring the insulating container 20, by using a conductive adhesive 17 or the like.

The loading portion 6 in which the quartz crystal vibrating element 10 is accommodated, is sealed by seam welding of the cover 16 and the insulating container 20 (third substrate 9) through the seal ring 15 which is provided on the upper surface of the third substrate 9 configuring the insulating container 20. The cover 16 is also called a lid, and can be formed, for example, using metal such as 42 alloy (alloy containing 42% of nickel in iron) or Kovar (alloy of iron, nickel, and cobalt), ceramics, or glass. In a case where the cover 16 is formed by metal, for example, the seal ring 15 is formed by die cutting of the Kovar alloy or the like in a rectangular ring shape. Since the loading portion 6 which is a recessed space formed by the insulating container 20 and the cover 16 is a space for operating the quartz crystal vibrating element 10, it is preferable to be hermetically sealed and enclosed to be a reduced-pressure space or to have inert gas atmosphere.

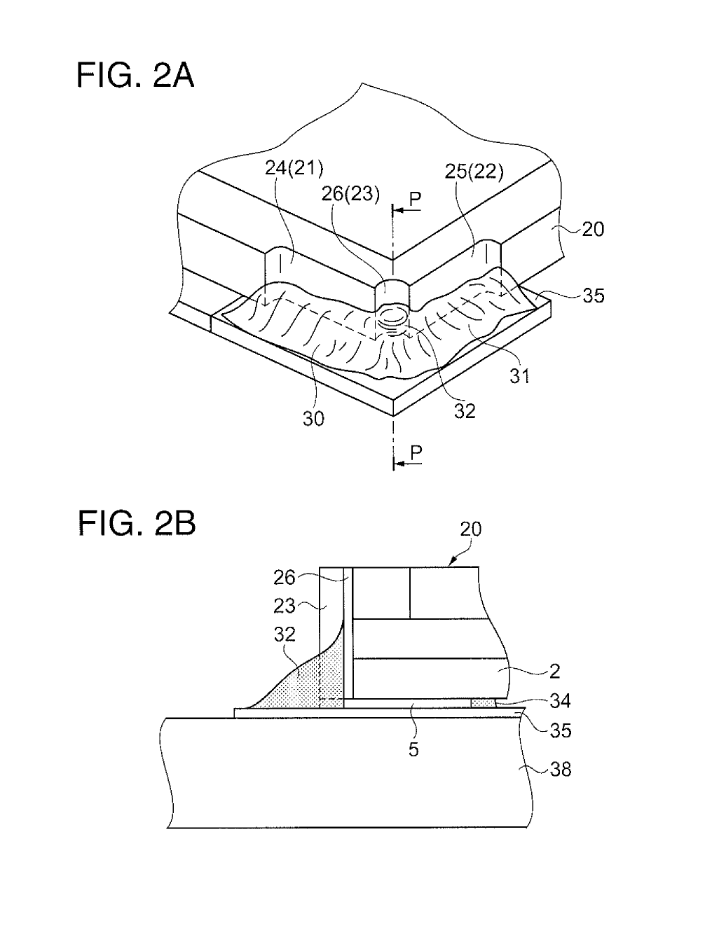

The quartz crystal resonator 1 of the above configuration is mounted by soldering or the like on a circuit board, another printed circuit board, or the like. The mounting thereof will be described using FIGS. 2A and 2B. FIGS. 2A and 2B are views showing a state of solder fillets of the surface-mounted quartz crystal resonator, wherein FIG. 2A is a perspective view and FIG. 2B is a cross-sectional view taken along line P-P of FIG. 2A. FIGS. 1A to 1C are also referred to in the description.

As shown in FIGS. 2A and 2B, when performing surface mounting of the surface-mounted quartz crystal resonator 1 using the insulating container 20 as the base substrate according to the invention on the motherboard circuit board, which is for example, the printed circuit board 38, the mounting electrodes 5 are on lands 35 of the printed circuit board 38 in a corresponding manner to each other in a one-to-one relationship, and they are connected by soldering. At that time, solder fillets (solder) 30, 31, 32, and 34 on the corner portion 7 which is in a position farthest from the center of the rectangular bottom surface of the insulating container 20 are necessary to sufficiently resist with respect to stress caused by a heat cycle or the like. That is, it is necessary that the solder fillets (solder) 30, 31, 32, and 34 continuously secure the electrical connection between the second terminals 26, 24, and 25 provided on the surfaces of the first cut-out portion 23, the second cut-out portion 21, and the third cut-out portion 22 or mounting electrodes 5, and the lands 35.

Accordingly, in the insulating container 20 according to the invention, on the side surfaces of four corner portions 7 of the insulating container 20 included in the mounting electrodes 5, first cut-out portions (castellation) 23 which are formed to include curved lines and to be recessed towards the center side when the insulating container 20 is seen in a plan view, are provided. Two elongated hole-shaped second cut-out portions 21 and the third cut-out portion 22 which extend from the first cut-out portion 23 to both sides are provided with the first cut-out portion 23 interposed therebetween.

In such a configuration, the solder fillet 30 formed on the portion of the second cut-out portion 21 and the solder fillet 31 formed on the portion of the third cut-out portion 22 are connected to each other by the solder fillet 32 formed on the first cut-out portion 23. That is, since the solder amounts in the first cut-out portion 23 provided between the second cut-out portion 21 and the third cut-out portion 22 are sufficiently secured, it is possible to prevent separation of the solder fillets 30 and 31 formed on both sides of the second cut-out portion 21 and the third cut-out portion 22. As described above, by connecting the solder fillets from the solder fillet 30, to the solder fillet 31 through the solder fillet 32, it is possible to form the solder fillets (solder) 30, 31, and 32 on the corner portion 7 which is in a position farthest from the center of the rectangular bottom surface of the insulating container 20 with sufficient solder amounts. That is, a space between solder fillets generated due to repulsion between the solder fillets on the corner portions which was a concern in the example of the related art, is not formed.

Accordingly, even when thermal load such as a so-called temperature cycle (for example, from +150° C. to −55° C.) in which the high temperature and the low temperature are repeatedly applied, is applied to the quartz crystal resonator 1, since the solder amounts (solder fillets) on the corner portion 7 in which maximum strain occurs are sufficient and the soldering area is sufficient, it is possible to prevent occurrence of cracks on the solder.

Therefore, it is possible to suppress and prevent malfunction such as occurrence of solder cracks due to the thermal load in the state where the surface-mounted quartz crystal resonator 1 using the insulating container 20 as the base substrate according to the invention is surface-mounted on the circuit substrate, for example, the printed circuit board 38. Particularly, it is possible to provide the surface-mounted quartz crystal resonator 1 which can sufficiently withstand usage in an environment having a wide temperature range, for example, from +150° C. to −55° C.

In the embodiments described above, the example of the quartz crystal resonator using the quartz crystal for a piezoelectric material as one example of the resonator has been described, however it is not limited thereto. A resonator which is obtained by loading the vibrating element using lithium tantalate (LiTaO₃), lithium tetraborate (Li₂B₄O₇), lithium niobate (LiNbO₃), lead zirconate titanate (PZT), zinc oxide (ZnO), aluminum nitride (AlN), or the like, or a semiconductor material such as silicon, as another piezoelectric element, may be used as the resonator.

### Modification Example 1 of Mounting Electrodes (First Terminals)

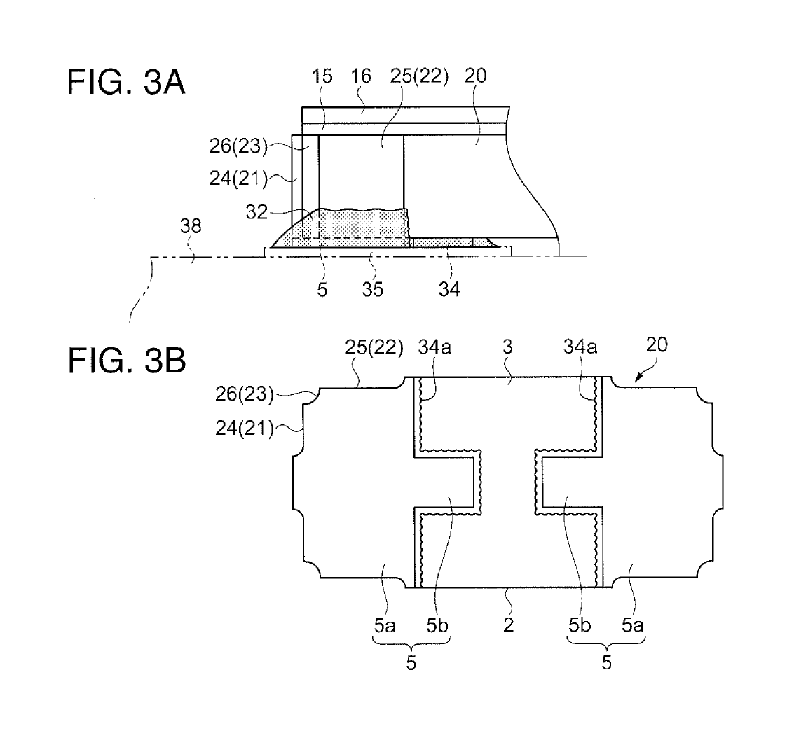

Next, Modification Example 1 of the mounting electrodes as the first terminals will be described with reference to FIGS. 3A and 3B. FIGS. 3A and 3B are views showing Modification Example 1 of the mounting electrodes, wherein FIG. 3A is a partial front view and FIG. 3B is a bottom view. The description of the same configuration as the embodiment described above will be omitted by denoting the same reference numerals. In the drawings, the second terminal 26 formed on the surface of the first cut-out portion 23, the second terminal 24 formed on the surface of the second cut-out portion 21, and the second terminal 25 formed on the surface of the third cut-out portion 22 are only described with the reference numerals and are omitted in the drawings.

As shown in FIGS. 3A and 3B, each of the mounting electrodes 5 as the first terminals according to Modification Example 1 is provided to include two corners of the rectangular bottom surface (the other surface) 3 of the first substrate 2, in a plan view, configuring the insulating container 20. Each of the mounting electrodes 5 includes a first portion 5a which includes the first cut-out portion 23, and the two elongated hole-shaped second cut-out portion 21 and the third cut-out portion 22 which extend to both sides with the first cut-out portion 23 interposed therebetween, and a second portion 5b which is protruded from the first portion 5a towards the center portion of the bottom surface (the other surface) 3. The second portions 5b are formed to interpose the center of the bottom surface (the other surface) 3 of the first substrate 2 in a short direction (width direction), and is formed to have a space which can sufficiently secure electrical insulation between the two facing second portions 5b.

By providing the mounting electrodes 5 of such a configuration, when applying the thermal load, the length of the soldering on the center portion of the insulating container 20 having a relatively small amount of expansion can be set longer, that is, the soldering area can be set larger. Accordingly, the strength of the soldering of the insulating container 20 can be further increased, in addition to the effect described above obtained by providing the three cut-out portions 23, 21, and 22. In addition, as shown by a wave line 34A in the drawing, since the elongated length of the end of the mounting electrodes 5 of the bottom surface (the other surface) 3 of the first substrate 2 on the center side can be set longer, it is possible to set the length formed by the solder fillet 34 on the inner side longer and the strength of the soldering can be improved.

### Modification Example 2 of Mounting Electrode (First Terminal)

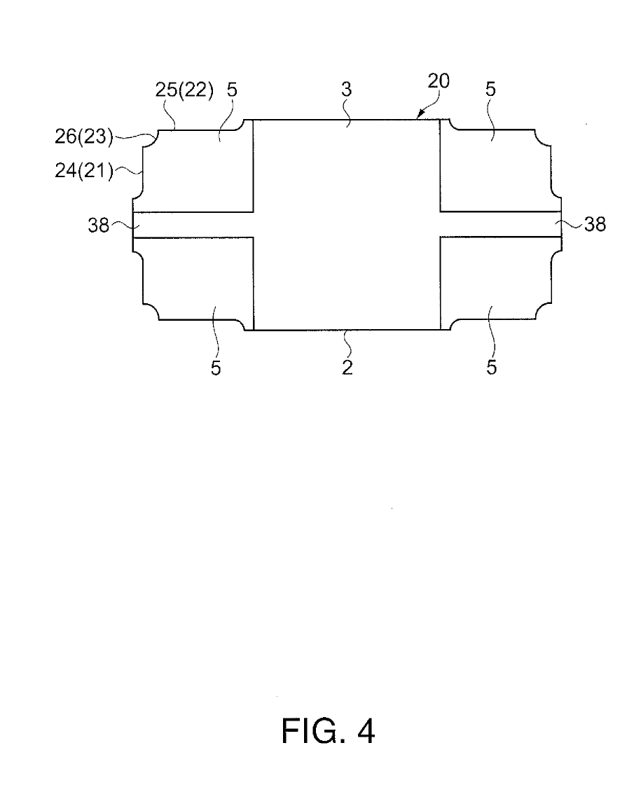

Next, Modification Example 2 of the mounting electrodes as the first terminals will be described with reference to FIG. 4. FIG. 4 is a bottom view showing Modification Example 2 of the mounting electrodes. In addition, the description of the same configuration as the embodiment described above will be omitted by denoting the same reference numerals. In the drawing, the second terminal 26 formed on the surface of the first cut-out portion 23, the second terminal 24 formed on the surface of the second cut-out portion 21, and the second terminal 25 formed on the surface of the third cut-out portion 22 are only described with the reference numerals and are omitted in the drawings.

As shown in FIG. 4, for the mounting electrodes 5 as the first terminals according to Modification Example 2, four mounting electrodes 5 are provided so as to include one of four corners of the rectangular bottom surface (the other surface) 3, in a plan view, of the first substrate 2 configuring the insulating container 20, for each mounting electrode 5.

With such a configuration, the different electrode corresponding to each mounting electrode 5 can be soldered. In addition, it is also possible to realize improvement of the strength of the soldering in the same manner as the embodiment described above.

### Modification Example 3 of Mounting Electrodes (First Terminals)

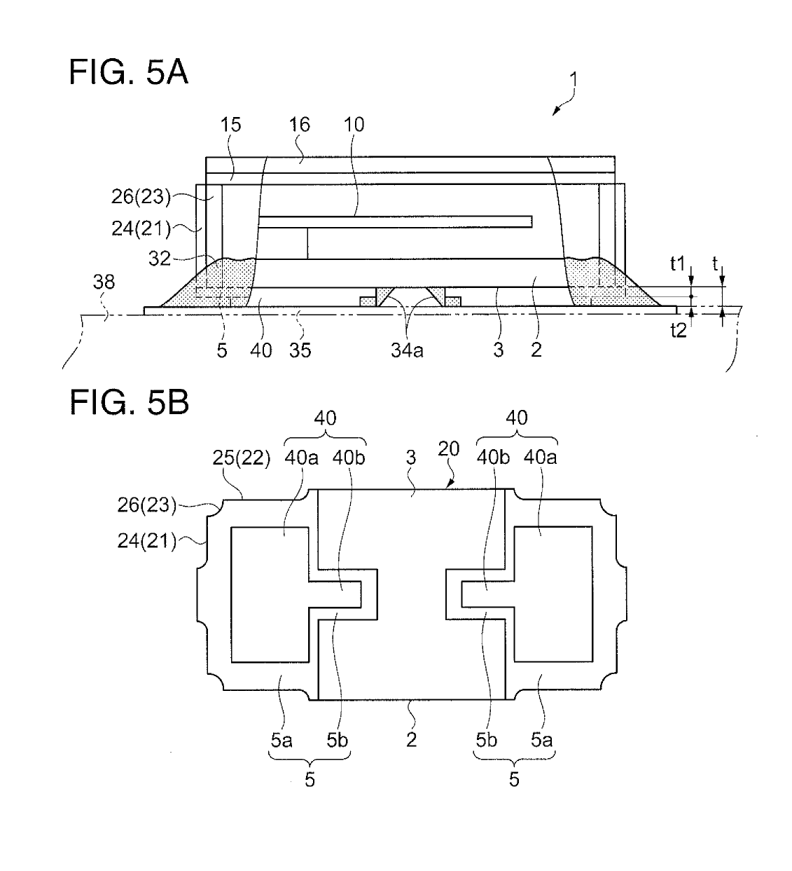

Next, Modification Example 3 of the mounting electrodes as the first terminals will be described with reference to FIGS. 5A and 5B. FIGS. 5A and 5B are views showing Modification Example 3 of the mounting electrodes, wherein FIG. 5A is a front view of the partial cross section and FIG. 5B is a bottom view. In addition, the description of the same configuration as the embodiment described above will be omitted by denoting the same reference numerals. In the drawings, the second terminal 26 formed on the surface of the first cut-out portion 23, the second terminal 24 formed on the surface of the second cut-out portion 21, and the second terminal 25 formed on the surface of the third cut-out portion 22 are only described with the reference numerals and are omitted in the drawings.

As shown in FIGS. 5A and 5B, each of the mounting electrodes 5 as the first terminals according to Modification Example 3 is formed to include a thick portion 40 having a greater thickness than a thickness of the periphery portion of the mounting electrode 5. That is, each of the mounting electrodes 5 of Modification Example 3 includes a periphery portion, and has a two-step structure in which the stepwise (protruded) thick portion 40 is provided surrounding the periphery portion.

Each of the mounting electrodes 5 of Modification Example 3 is provided to include two corners of the approximately rectangular bottom surface (the other surface) 3, in a plan view, of the first substrate 2 configuring the insulating container 20. Each of the mounting electrodes 5 includes a first portion 5a which includes the first cut-out portion 23, and the two elongated hole-shaped second cut-out portion 21 and the third cut-out portion 22 which extend to both sides with the first cut-out portion 23 interposed therebetween, and a second portion 5b which protrudes from the first portion 5a towards the center portion of the bottom surface (the other surface) 3. The second portions 5b are formed to interpose the center of the bottom surface (the other surface) 3 of the first substrate 2 in the short direction (width direction), and are formed to have a sufficient space for electrical insulation between the two facing second portions 5b.

The thick portion 40 is provided as a protrusion having a greater thickness than the thickness of the periphery portion on the inner side of the periphery portion which is the outer periphery of the mounting electrode 5. That is, the thick portion 40 is a step portion, the outer periphery of which is surrounded by the thin periphery portion. Accordingly, the thick portion 40 has a shape which is contracted so as to substantially follow the shape of the mounting electrode 5 of Modification Example 3 described above, and a first thick portion 40a is formed on a region of the first portion 5a of the mounting electrode 5, and a second thick portion 40b is formed on a region of the second portion 5b of the mounting electrode 5.

By providing the mounting electrodes 5 having such a two-step configuration of Modification Example 3, the thickness of the mounting electrode 5 can be set greater. That is, as shown in FIG. 5B, a thickness t of the mounting electrode 5 is a thickness obtained by adding a thickness t1 of a first step and a thickness t2 of a second step. As described above, by setting the thickness of the mounting electrode 5 greater, it is possible to provide a space for filling the solder on the periphery portion of the mounting electrode 5, and the space between the bottom surface 3 of the first substrate 2 and the land 35 of the printed circuit board 38 is also widened. Since the solder flows into the widened space, it is possible to have a greater solder amount when soldering. In addition, since the solder fillets are also formed on the second cut-out portion 21, the third cut-out portion 22, and the first cut-out portion 23, it is possible to obtain further sufficient strength of soldering and reliability.

### Modification Example 4 of Mounting Electrodes (First Terminals)

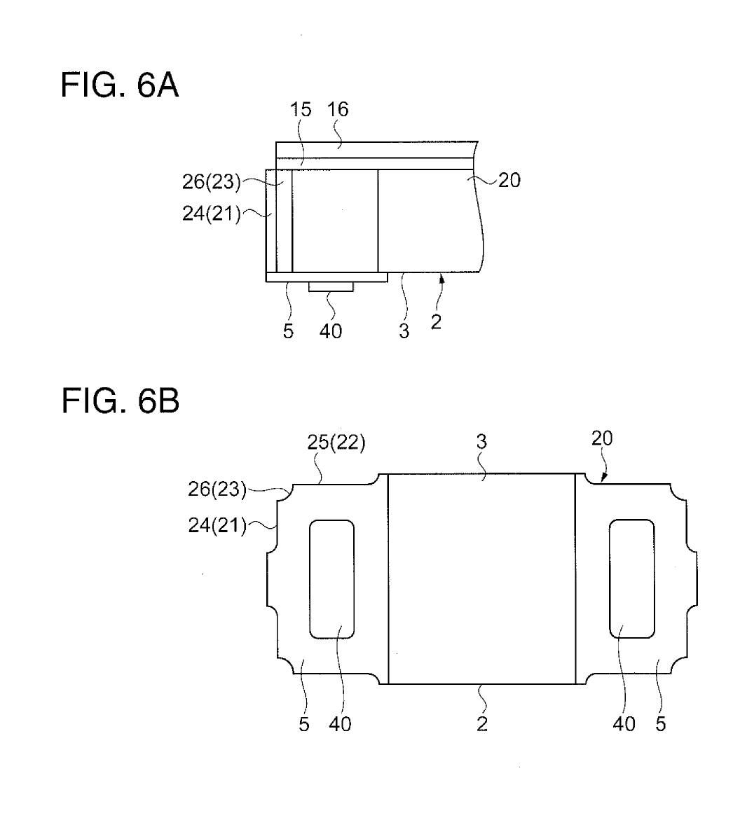

Next, Modification Example 4 of the mounting electrodes as the first terminals will be described with reference to FIGS. 6A and 63. FIGS. 6A and 63 are views showing Modification Example 4 of the mounting electrodes, wherein FIG. 6A is a partial front view and FIG. 63 is a bottom view. The description of the same configuration as the embodiment described above will be omitted by denoting the same reference numerals. In the drawings, the second terminal 26 formed on the surface of the first cut-out portion 23, the second terminal 24 formed on the surface of the second cut-out portion 21, and the second terminal 25 formed on the surface of the third cut-out portion 22 are only described with the reference numerals and are omitted in the drawings.

As shown in FIGS. 6A and 6B, each of the mounting electrodes 5 as the first terminals according to Modification Example 4 is formed to include a thick portion 40 having a greater thickness than a thickness of the periphery portion of the mounting electrode 5. That is, each of the mounting electrodes 5 of Modification Example 4 includes a periphery portion, and has a two-step structure in which the stepwise (protruded) thick portion 40 is provided surrounding the periphery portion.

The thick portion 40 is disposed on the outer periphery side (end side in longitudinal direction) with respect to the center of the bottom surface 3 of the first substrate 2, and is provided as a protrusion having a greater thickness than a thickness of the periphery portion on the inner side of the periphery portion which is the outer periphery of the mounting electrode 5. That is, the thick portion 40 is a step portion, the outer periphery of which is surrounded by the thin outer periphery portion.

In the mounting electrodes 5 having such a two-step configuration of Modification Example 4, the thickness of the mounting electrode 5 can be set greater. In the same manner as Modification Example 3 described above, by setting the thickness of the mounting electrodes 5 greater, it is possible to provide a space for filling the solder on the periphery portion of the mounting electrode 5, and the space between the bottom surface 3 of the first substrate 2 and the land 35 of the printed circuit board 38 is also widened. In this example, since the thick portion 40 is on the outer periphery side with respect to the center of the bottom surface 3 of the first substrate 2, it is possible to have a greater solder amount on the center portion side in which the deformation amount due to thermal expansion is relatively small. In addition, since the solder fillets are also formed on the second cut-out portion 21, the third cut-out portion 22, and the first cut-out portion 23, it is possible to obtain further sufficient strength of soldering and reliability.

### Modification Example 5 of Mounting Electrodes (First Terminals)

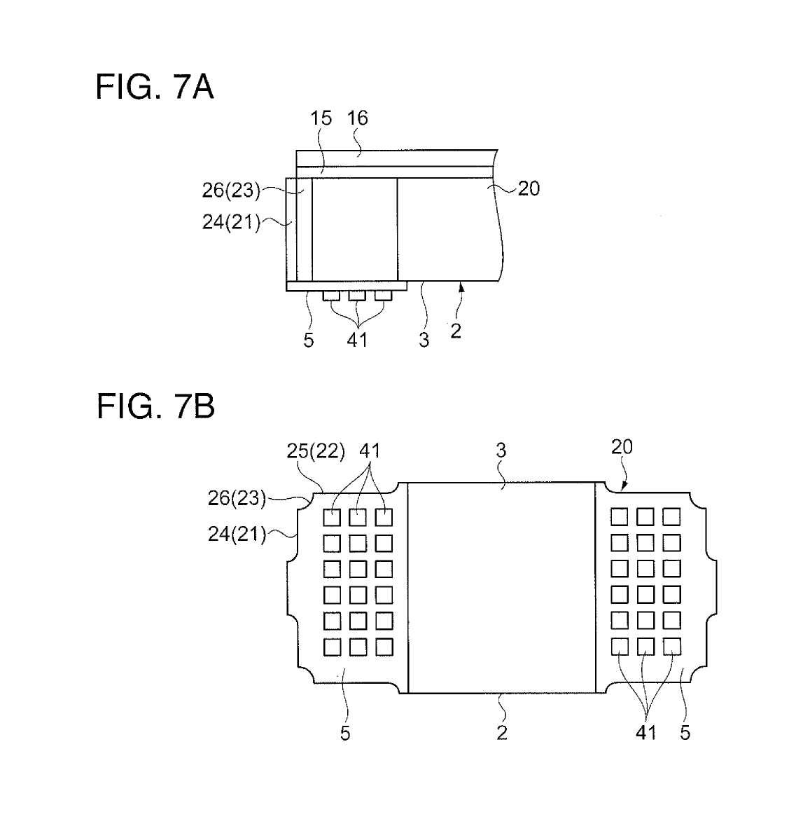

Next, Modification Example 5 of the mounting electrodes as the first terminals will be described with reference to FIGS. 7A and 7B.

FIGS. 7A and 7B are views showing Modification Example 5 of the mounting electrodes, wherein FIG. 7A is a partial front view and FIG. 7B is a bottom view. The description of the same configuration as the embodiment described above will be omitted by denoting the same reference numerals. In the drawings, the second terminal 26 formed on the surface of the first cut-out portion 23, the second terminal 24 formed on the surface of the second cut-out portion 21, and the second terminal 25 formed on the surface of the third cut-out portion 22 are only described with the reference numerals and are omitted in the drawings.

As shown in FIGS. 7A and 73, a plurality of protrusions 41 are provided on the surface of the mounting electrodes 5 as the first terminals according to Modification Example 5. Each of the protrusions 41 is provided as a protrusion having a greater thickness than the thickness of the mounting electrode 5.

By providing the mounting electrodes 5 of Modification Example 5, it is possible to fill the solder in the space provided by the plurality of protrusions 41, and accordingly it is possible to set the soldering area larger. Therefore, it is possible to improve the strength of the soldering and improve the reliability of the soldering.

### Oscillator

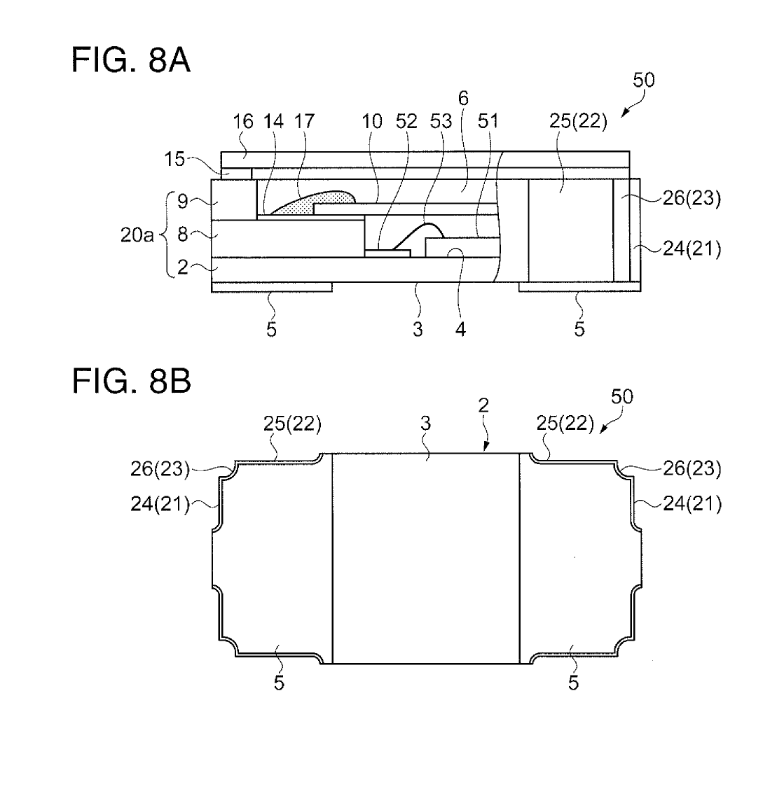

Next, a surface-mounted oscillator using the base substrate according to the invention will be described. FIGS. 8A and 8B show a schematic configuration of the surface-mounted oscillator according to one embodiment of the invention, wherein FIG. 8A is a partial longitudinal front cross-sectional view and FIG. 83 is a bottom view. In the description, the description of the same configuration as the embodiment of the surface-mounted quartz crystal resonator described above is omitted by denoting the same reference numerals.

An oscillator 50 shown in FIGS. 8A and 8B has a configuration of accommodating the quartz crystal vibrating element 10, and a circuit element (for example, semiconductor element) 51 at least having a function of driving the quartz crystal vibrating element 10, in the loading portion 6 which is a recess of an insulating container (package) 20a as a base substrate obtained by laminating the first substrate 2, the second substrate 8, and the third substrate 9 which are formed of a sheet-like insulating material such as ceramic sheet, and sealing a loading portion 6 with the cover 16. The oscillator 50 in this example is a quartz crystal oscillator using the quartz crystal vibrating element 10 using an AT-cut quartz crystal substrate, as one example.

The configuration of the insulating container 20a is almost the same as the first embodiment of the surface-mounted quartz crystal resonator 1 described above, however it is different from the first embodiment in that the insulating container includes a loading portion of the circuit element 51. The embodiment will be described with a focus on the different part.

The insulating container 20a is a circuit wiring board having an approximately rectangular container shape in a plan view, and the mounting electrodes (first terminals) 5 which are provided to contain two corners of the bottom surface (other surface) 3 of the approximately rectangular first substrate 2 are provided. In the insulating container 20a, the loading portion 6 which is a recess surrounded by an opening portion of the second substrate 8 and the third substrate 9 is provided on the other surface 4 side which has a front and rear relationship with the bottom surface 3 of the first substrate 2. The circuit element 51 is fixed to the other surface 4 with an adhesive or the like (not shown), and is electrically connected to a wiring terminal 52 provided on the other surface 4 by a wire-bonding wire 53. The wiring terminal 52 is electrically connected to an inner pad 14, which will be described later, or the mounting electrodes (first terminals) 5, however the electrical connection is omitted in the drawing. The other surface 4 is a surface on a side of the insulating container 20a which is connected to the cover 16, and indicates one surface of the first substrate 2 in the drawing for the sake of convenience. Two inner pads 14 which are electrically connected to the quartz crystal vibrating element 10 are provided on an exposed surface of the second substrate 8 which is exposed in the loading portion 6. In the same manner as described above, the first cut-out portion 23, the second cut-out portion 21, and the third cut-out portion 22 are provided on the insulating container 20a, and the second terminals 26, 24, and 25 which are metallic layers are provided on the surfaces thereof.

The circuit element 51 includes a driving circuit or the like as an excitation unit for driving and excitation of the quartz crystal vibrating element 10. More specifically, the driving circuit included in the circuit element 51 drives the quartz crystal vibrating element 10, and supplies a received driving signal to an external portion by amplifying or the like.

The loading portion 6 in which the quartz crystal vibrating element 10 and the circuit element 51 are accommodated, is sealed by seam welding of the cover 16 and the insulating container 20a (third substrate 9) through the seal ring 15 which is provided on the upper surface of the third substrate 9 configuring the insulating container 20a. The cover 16 is also called a lid, and can be formed, for example, using metal such as 42 alloy (alloy containing 42% of nickel in iron) or Kovar (alloy of iron, nickel, and cobalt), ceramics, or glass. In a case where the cover 16 is formed by metal, for example, the seal ring 15 is formed by die cutting of the Kovar alloy or the like in a rectangular ring shape. Since the loading portion 6 which is a recessed space formed by the insulating container 20a and the cover 16 is a space for operating the quartz crystal vibrating element 10, it is preferable to be hermetically sealed and enclosed to be a reduced-pressure space or to have inert gas atmosphere.

According to the oscillator 50, in the same manner as the quartz crystal resonator 1 described above, it is possible to form the solder fillets (solder) 30, 31, and 32 on the corner portion 7 which is in a position farthest from the center of the rectangular bottom surface of the insulating container 20a with sufficient solder amounts. That is, a space between solder fillets generated due to repulsion between the solder fillets on the corner portions which was a concern in the example of the related art, is not formed.

Accordingly, even when thermal load such as a so-called temperature cycle (for example, from +150° C. to −55° C.) in which the high temperature and the low temperature are repeatedly applied, is applied to the oscillator 50, since the solder amounts (solder fillets) on the corner portion 7 in which maximum strain occurs are sufficient and the soldering area is sufficient, it is possible to prevent occurrence of cracks on the solder. Therefore, it is possible to suppress and prevent malfunction such as occurrence of solder cracks due to the thermal load in the state where the surface-mounted oscillator 50 using the insulating container 20a as the base substrate according to the invention is surface-mounted on the circuit substrate or another printed circuit board.

In the above description, the quartz crystal oscillator using the quartz crystal vibrating element 10 using the AT-cut quartz crystal substrate as one example of the vibrating element has been described as an example, however, the vibrating element is not limited thereto. For example, a tuning fork quartz crystal resonator, a surface acoustic wave element, a Micro Electro Mechanical Systems (MEMS), or the like may be used. In addition, a configuration obtained by applying a vibrating element using the other piezoelectric material described in the resonator may be used.

### Sensor Device

The insulating containers 20 and 20a using the base substrate according to the invention can be applied to a sensor device obtained by loading a sensor element such as a gyro sensor element, an acceleration sensor element, or a pressure sensor element, instead of the quartz crystal vibrating element 10 as the vibrating element described above.

According to the sensor device, in the same manner as the quartz crystal oscillator described above, it is possible to suppress and prevent malfunction such as occurrence of solder cracks due to the thermal load in the state of being surface-mounted on the circuit substrate or another printed circuit board.

### Electronic Device

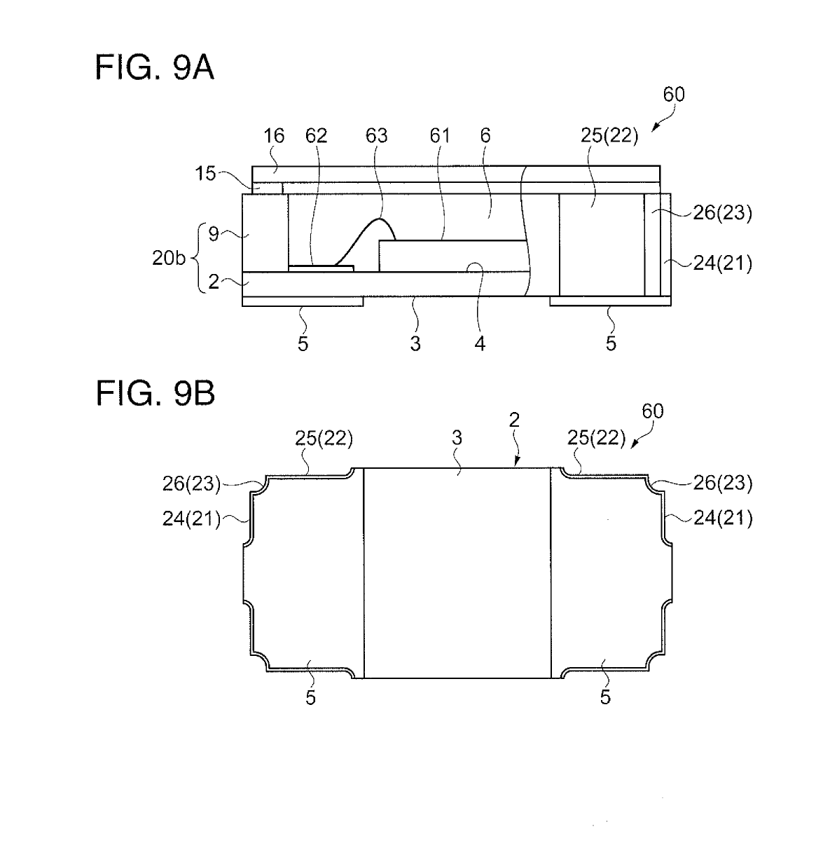

Next, a surface-mounted electronic device using the base substrate according to the invention will be described. FIGS. 9A and 9B show a schematic configuration of the surface-mounted electronic device according to one embodiment of the invention, wherein FIG. 7A is a partial longitudinal front cross-sectional view and FIG. 7B is a bottom view. In this description, the same configuration as the embodiment of the surface-mounted quartz crystal resonator described above will be omitted by denoting the same reference numerals.

An electronic device 60 shown in FIGS. 9A and 9B has a configuration of accommodating a circuit element (for example, semiconductor element) 61 in the loading portion 6 which is a recess of an insulating container (package) 20b as a base substrate obtained by laminating the first substrate 2 and the third substrate 9 which are formed of a sheet-like insulating material such as ceramics, and sealing the loading portion 6 with the cover 16.

The configuration of the insulating container 20b is almost the same as the embodiment of the surface-mounted quartz crystal resonator 1 described above, except for not including the second substrate 8, however, it is different from the first embodiment in that the insulating container includes a loading portion of the circuit element 61, instead of the loading portion of the quartz crystal resonator 1. The embodiment will be described with a focus on the different part.

The insulating container 20b is a circuit wiring board having an approximately rectangular container shape in a plan view, and the mounting electrodes (first terminals) 5 which are provided to contain two corners of the bottom surface (other surface) 3 of the approximately rectangular first substrate 2 are provided. In the insulating container 20b, the loading portion 6 which is a recess surrounded by an opening portion of the third substrate 9 is provided on the other surface 4 side which has a front and rear relationship with the bottom surface 3 of the first substrate 2. The circuit element 61 is fixed to the other surface 4 with an adhesive (not shown) or the like, and is electrically connected to a wiring terminal 62 provided on the other surface 4 by a wire-bonding wire 63. The wiring terminal 62 is electrically connected to the mounting electrodes (first terminals) 5, however it is omitted in the drawing. The other surface 4 is a surface on a side of the insulating container 20b which is connected to the cover 16, and indicates one surface of the first substrate 2 in the drawing for the sake of convenience. In the same manner as described above, the first cut-out portion 23, the second cut-out portion 21, and the third cut-out portion 22 are provided on the insulating container 20b, and the second terminals 26, 24, and 25 which are metallic layers are provided on the surfaces thereof.

The circuit element 61 includes, for example, a driving circuit as an excitation unit for driving and vibration of the piezoelectric vibrating element or an electronic circuit for controlling the electronic apparatus.

The loading portion 6 in which the circuit element 51 is accommodated, is sealed by seam welding of the cover 16 and the insulating container 20b (third substrate 9) through the seal ring 15 which is provided on the upper surface of the third substrate 9 configuring the insulating container 20b. The cover 16 is also called a lid, and is formed, for example, by die cutting of the Kovar alloy or the like in a rectangular ring shape. The loading portion 6 which is a recessed space formed by the insulating container 20b and the cover 16 is preferably hermetically sealed and enclosed to be a reduced-pressure space or to have inert gas atmosphere for preventing degradation of the circuit element 61.

According to the electronic device 60, in the same manner as the quartz crystal resonator 1 described above, it is possible to form the solder fillets (solder) 30, 31, and 32 on the corner portion 7 which is in a position farthest from the center of the rectangular bottom surface of the insulating container 20b with sufficient solder amounts. That is, a space between solder fillets generated due to repulsion between the solder fillets on the corner portions which was a concern in the example of the related art, is not formed.

Accordingly, even when thermal load such as a so-called temperature cycle (for example, from +150° C. to −55° C.) in which the high temperature and the low temperature are repeatedly applied, is applied to the electronic device 60, since the solder amounts (solder fillets) on the corner portion in which maximum strain occurs are sufficient and the soldering area is sufficient, it is possible to prevent occurrence of cracks on the solder.

Therefore, it is possible to suppress and prevent malfunction such as occurrence of solder cracks due to the thermal load in the state where the surface-mounted electronic device 60 using the insulating container 20b as the base substrate according to the invention is surface-mounted on the circuit substrate or another printed circuit board.

In the description of the electronic device described above, the electronic device 60 of the configuration using the circuit element 61 has been described as an example, however the invention is not limited thereto, and for example, the invention can also be applied to a configuration of connecting various electronic components to a circuit pattern formed on the other surface 4, or a configuration of loading another electronic element.

In the resonator, the oscillator, the sensor device, and the electronic device described above, the example of loading and forming elements such as the quartz crystal vibrating element 10, the circuit elements 51 and 61 or wiring on the loading portion 6 provided on the other surface 4 side has been described, however, the invention is not limited thereto. In the resonator, the oscillator, the sensor device, and the electronic device according to the invention, configuration of providing the loading portion on one surface (bottom surface 3) side may be used, or a configuration of loading and forming elements such as the quartz crystal vibrating element 10, the circuit elements 51 and 61 or wiring on the loading portion of the one surface (bottom surface 3) side may be used, and the same effects can be obtained.

### Electronic Apparatus

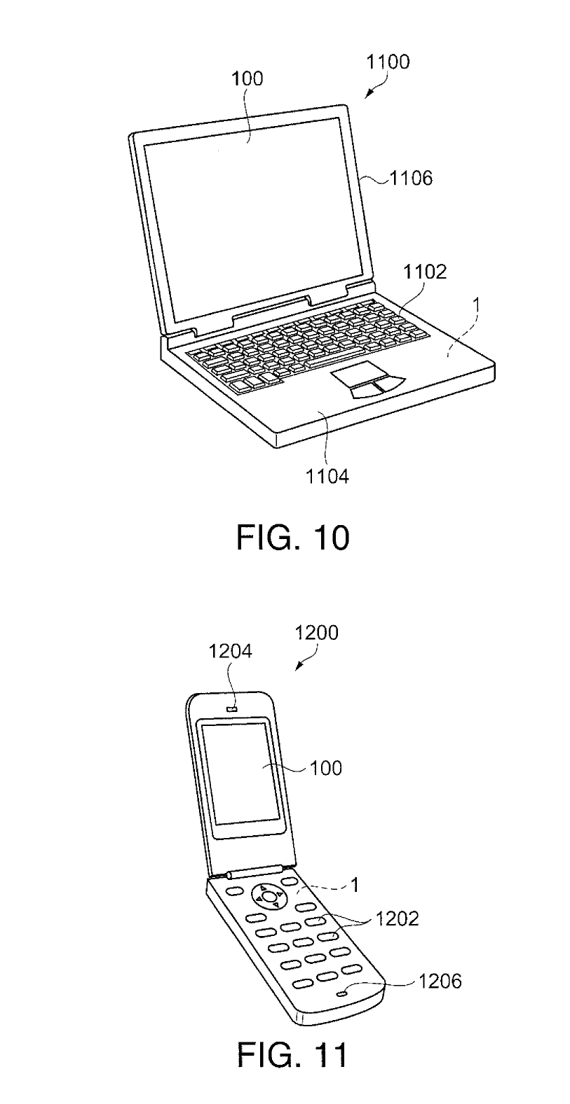

An electronic apparatus obtained by applying the surface-mounted quartz crystal resonator 1, the oscillator 50, the electronic device 60, the sensor device, or the like as the surface-mounted device using the base substrate according to one embodiment of the invention, will be described in detail, with reference to FIGS. 10 to 12. In the description, the examples to which the quartz crystal resonator 1 is applied will be shown.

FIG. 10 is a schematic perspective view showing a configuration of a mobile type (or note type) personal computer as an electronic apparatus including the quartz crystal resonator 1 according to one embodiment of the invention. In this example, a personal computer 1100 is configured with a main body portion 1104 including a keyboard 1102, and a display unit 1106 including a display portion 100, and the display unit 1106 is rotatable supported through a hinge structure with respect to the main body portion 1104. The quartz crystal resonator 1 is mounted in such personal computer 1100, as a reference signal source or the like.

FIG. 11 is a schematic perspective view showing a configuration of a mobile phone (including PHS) as an electronic apparatus including the quartz crystal resonator 1 according to one embodiment of the invention. In the drawing, a mobile phone 1200 includes a plurality of manipulation buttons 1202, an ear piece 1204, and a mouth piece 1206, and the display portion 100 is disposed between the manipulation buttons 1202 and the ear piece 1204. The quartz crystal resonator 1 is mounted in such mobile phone 1200, as a reference signal source or the like.

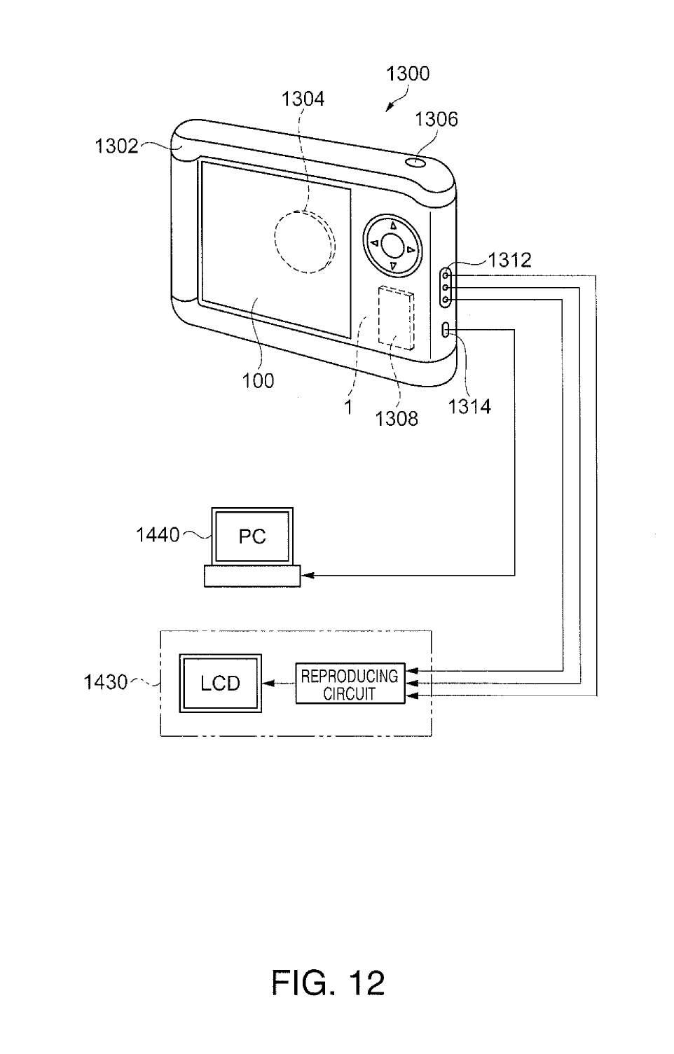

FIG. 12 is a schematic perspective view showing a configuration of a digital still camera as an electronic apparatus including the quartz crystal resonator 1 according to one embodiment of the invention. In this drawing, connection with an external device is also simply shown. Herein, while a typical camera exposes a silver halide photography film to light by a light image of a subject, the digital still camera 1300 performs photoelectric conversion of the light image of the subject by an image element such as a charged coupled device (CCD) and generates an imaging signal (image signal). The display portion 100 is provided on a rear surface of a case (body) 1302 of the digital still camera 1300 and has a configuration of performing display based on the imaging signal generated by the CCD, and the display portion 100 functions as a finder which displays the subject as an electronic image. In addition, a light receiving unit 1304 including an optical lens (imaging optical system), CCD, or the like is provided on a front surface side (rear surface side in the drawing) of the case 1302.

If a photographer confirms a subject image displayed on the display portion 100 and presses a shutter button 1306, an imaging signal of CCD at this time point is transferred and stored in a memory 1308. In the digital still camera 1300, a video signal output terminal 1312 and an input and output terminal for data communication 1314 are provided on a side surface of the case 1302. As shown in the drawing, the video signal output terminal 1312 is connected to a television monitor 1430, and the input and output terminal for data communication 1314 is connected to a personal computer 1440, if necessary. With predetermined manipulation, the imaging signal stored in the memory 1308 is output to the television monitor 1430 or the personal computer 1440. The quartz crystal resonator 1 is mounted in such digital still camera 1300, as a reference signal source or the like.

In addition, in addition to the personal computer (mobile type personal computer) in FIG. 10, the mobile phone in FIG. 11, and the digital still camera in FIG. 12, the quartz crystal resonator 1 according to one embodiment of the invention, for example, can be applied to an electronic apparatus such as an ink jet type discharging apparatus (for example, ink jet printer), a laptop type personal computer, a television, a video camera, a video tape recorder, a car navigation apparatus, a pager, an electronic organizer (including communication function), an electronic dictionary, a calculator, an electronic game machine, a word processor, a workstation, a videophone, a security television monitor, an electronic binocular, a POS terminal, medical equipment (for example, an electronic thermometer, a blood pressure meter, a blood glucose meter, an electrocardiogram measuring device, an ultrasonic diagnostic apparatus, and an electronic endoscope), fish finder, various measurement equipments, meters (for example, meters of a vehicle, an aircraft, a ship), a flight simulator, or the like.

### Moving Object

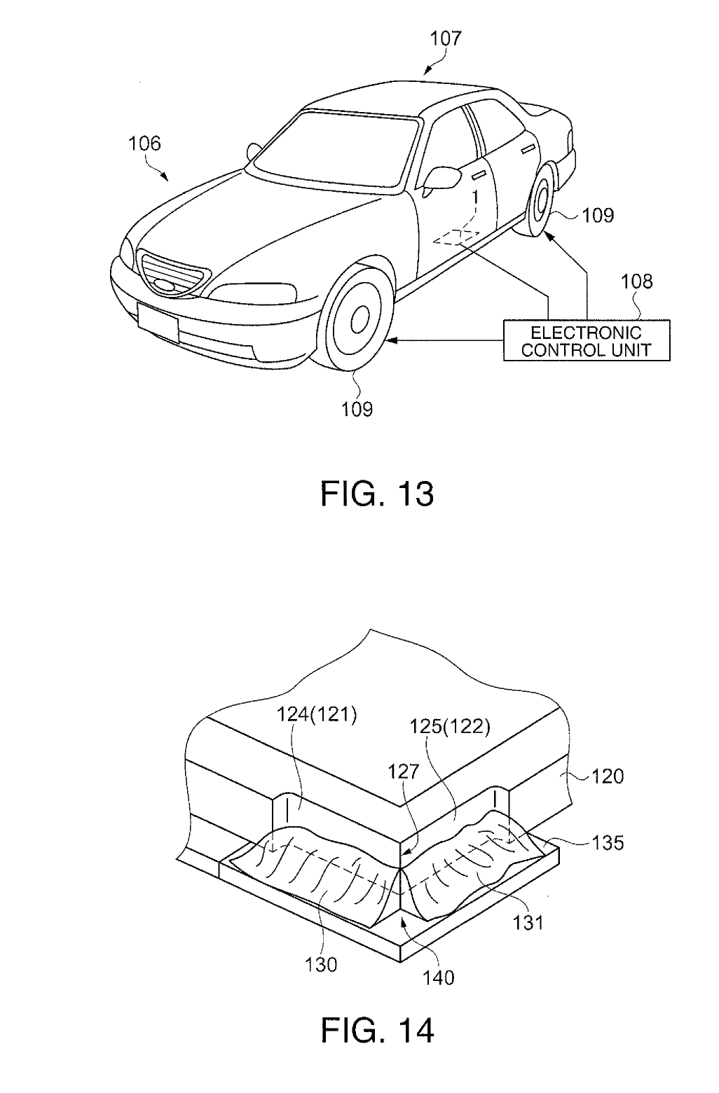

FIG. 13 is a perspective view schematically showing a vehicle as one example of a moving object. The quartz crystal resonator 1 according to the invention is mounted in a vehicle 106. For example, as shown in the drawing, the quartz crystal resonator 1 is mounted in the vehicle 106 as a moving object, and an electronic control unit 108 for controlling tires 109 and the like is loaded on a car body 107. In addition thereof, the quartz crystal resonator 1 can be widely applied to electronic control units (ECU) of a keyless entry device, an immobilizer, car navigation systems, car air conditioners, an anti-lock brake system (ABS), airbags, tire pressure monitoring system (TPMS), engine control, a battery monitor of a hybrid car or an electric car, a car body attitude control system, and the like. Particularly, the quartz crystal resonator 1 according to the invention is suitable for the vehicle 106 which can be used in a wide temperature range and is used in a severe temperature environment, since it can improve reliability with respect to the temperature load of soldering.

The entire disclosure of Japanese Patent Application No. 2012-265017, filed Dec. 4, 2012 is expressly incorporated by reference herein.

What is claimed is:

1. A base substrate comprising a substrate which has corner portions and cut-out portions obtained by connecting side surfaces on both sides of the corner portions, in a plan view, and in which an outer periphery of the corner portion is a curved line, in a plan view,
wherein a metallic film is provided on a surface of each of the cut-out portions.

2. The base substrate according to claim 1,
wherein the outer periphery of each of the corner portions is convexly recessed towards the center of the substrate, in a plan view.

3. The base substrate according to claim 1, further comprising:
mounting terminals on one surface of the substrate,
wherein concavity and convexity are provided on the surface of each of the mounting terminals.

4. A resonator comprising:
the base substrate according to claim 1; and
a vibrating piece which is loaded on the base substrate.

5. A resonator comprising:
the base substrate according to claim 2; and
a vibrating piece which is loaded on the base substrate.

6. An oscillator comprising:
the base substrate according to claim 1;
a vibrating piece which is loaded on the base substrate; and
a circuit.

7. An oscillator comprising:
the base substrate according to claim 2;
a vibrating piece which is loaded on the base substrate; and
a circuit.

8. An electronic device comprising:
the base substrate according to claim 1; and
an electronic element which is loaded on the base substrate.

9. An electronic device comprising:
the base substrate according to claim 2; and
an electronic element which is loaded on the base substrate.

10. A sensor comprising:
the base substrate according to claim 1; and
a sensor element which is loaded on the base substrate.

11. A sensor comprising:
the base substrate according to claim 2; and
a sensor element which is loaded on the base substrate.

12. An electronic apparatus comprising the base substrate according to claim 1.

13. An electronic apparatus comprising the base substrate according to claim 2.

14. A moving object comprising the base substrate according to claim 1.

15. A moving object comprising the base substrate according to claim 2.
